(19) United States
(12) Patent Application Publication
(10) Pub. No.: US 2026/0142106 A1
(43) Pub. Date: May 21, 2026

(54) HIGH-VOLTAGE CONNECTOR WITH JOINING GROOVE

(71) Applicant: PIERBURG GMBH, NEUSS (DE)

(72) Inventors: PETER KUESGEN, NEUSS (DE); JURI WAGNER, TITZ (DE); DANIEL FUHRMANN, REMSCHEID (DE)

(73) Assignee: PIERBURG GMBH, NEUSS (DE)

(21) Appl. No.: 19/383,790

(22) Filed: Nov. 10, 2025

(30) Foreign Application Priority Data
Nov. 19, 2024 (DE) 20 2024 106 659.6

(51) Int. Cl. H01H 36/00; H01H 1/20; H01H 9/04; H01H 9/30; H01H 33/18; H05K 5/06

(52) U.S. Cl. CPC H01H 36/008; H01H 1/2075; H01H 9/04; H01H 9/30; H01H 33/182; H05K 5/066; H01H 2009/305

(57) ABSTRACT

A high-voltage contactor includes an actuator having a coil and an armature which is movable via the coil, a housing having housing body and a housing cover which together enclose a contact chamber, and a contact bridge which is electrically conductive. The housing cover is connected to the housing body in a gas-tight manner via an ultrasonic-welded connection having a welding joint. The housing cover comprises a joining groove. The contact bridge is arranged in the contact chamber to be displaceable by the electromagnetic actuator into a contact position where a first stationary contact element is electrically connected to a second stationary contact element via the contact bridge, and into an open position in which an electrical contact is disconnected. A housing body wall protrudes into the joining groove. The welding joint of the ultrasonic-welded connection is formed by the joining groove and the housing body wall.

### CROSS REFERENCE TO PRIOR APPLICATIONS

Priority is claimed to German Patent Application No. DE 20 2024 106 659.6, filed Nov. 19, 2024. The entire disclosure of said application is incorporated by reference herein.

### FIELD

The present invention is directed to a high-voltage contactor or high-voltage relay with an electromagnetic actuator comprising a coil, a movable armature, a housing with a contact chamber, and a contact bridge which can be displaced in the contact chamber by the actuator into a first position, namely, the contact position, in which a first stationary contact element is electrically connected to a second stationary contact element via the contact bridge, and into a second position, namely, the opening position, in which electrical contact between the first contact element and the second contact element is disconnected.

### BACKGROUND

Such high-voltage contactors are required to connect and to disconnect electrical connections in an electrically load-free or load state, wherein voltages of over 1,000 V and currents of over 1,000 A can occur in the load state. Such loads can, for example, occur between the traction battery and the drive motor or between a charging station and the traction battery in a battery-powered electric vehicle.

The housing of such a high-voltage contactor is typically gas-tight so that no gas exchange with the environment is possible. The contact chamber is in particular gas-tight, which is advantageous to extinguish arcs that may occur when the contact bridge is disconnected from the contact elements.

### SUMMARY

An aspect of the present invention is to provide a high-voltage contactor with a gas-tight housing that can be manufactured relatively cost-efficiently.

In an embodiment, the present invention provides a high-voltage contactor which includes an electromagnetic actuator which comprises a coil and a ferromagnetic armature which is configured to be movable via the coil, a housing which comprises a housing body and a housing cover, and an electrically conductive contact bridge. The housing body and the housing cover are arranged to together enclose a contact chamber. The housing cover is connected to the housing body in a gas-tight manner via an ultrasonic-welded connection. The housing cover comprises a joining groove. The ultrasonic-welded connection comprises a welding joint. The electrically conductive contact bridge is arranged in the contact chamber and is configured to be displaceable by the electromagnetic actuator into a contact position in which a first stationary contact element is electrically connected to a second stationary contact element via the electrically conductive contact bridge, and into an open position in which an electrical contact between the first contact element and the second contact element is disconnected. A housing body wall protrudes into the joining groove. The welding joint of the ultrasonic-welded connection is formed by the joining groove and the housing body wall.

### BRIEF DESCRIPTION OF THE DRAWINGS

The present invention is described in greater detail below on the basis of embodiments and of the drawings in which:

FIG. 1 is a high-voltage contactor according to the present invention in a sectional view from the front showing the condition before the ultrasonic welding; and

FIG. 2 is an enlarged detailed view of the welding joint of the high-voltage contactor of FIG. 1.

### DETAILED DESCRIPTION

For purposes of simplicity, only the term high-voltage contactor will be used hereafter, although it also refers to a high-voltage relay. The terms radial, axial, and diametric furthermore refer to the center axis of the actuator along which the armature of the actuator can be moved linearly.

The high-voltage contactor according to the present invention comprises a linear electromagnetic actuator. An electromagnetic actuator in this context is to be understood as any actuator that generates a linear motion due to a force which is generated by electromagnetism. The electromagnetic actuator comprises a coil which can, for example, consist of a coil carrier and a winding wound thereon, as well as a ferromagnetic armature which is arranged, for example, inside the coil and which can be moved by the electromagnetic force of the activated actuator.

The high-voltage contactor also comprises a multi-part housing which can, for example, be made of plastic, the multi-part housing comprising a housing body and a housing cover, which together enclose a contact chamber that is arranged axially adjacent to the actuator. The housing cover closes the contact chamber at the axial end, while the other contact chamber walls bounding the contact chamber are formed by the housing body, the contact chamber walls being connected to each other in an airtight manner. The contact chamber walls on the housing body side can, for example, be integrally connected to each other.

The high-voltage contactor has a first and a second stationary contact element attached to the housing which both protrude into the contact chamber and may be connected permanently to a busbar outside the high-voltage contactor, one of which can lead to a traction battery in a motor vehicle and the other, for example, to a power electronics system for an electric vehicle drive motor or which can be connected to a charging station outside the vehicle. An electrical connection between these two contact elements can be established on demand via a contact bridge which is moved along a linear movement axis by the actuator in the contact chamber. By energizing a coil winding of the electromagnetic actuator, the contact bridge, whose ends may comprise two electrical contacts, is moved axially against the two contact elements attached to the housing in order to provide a relatively low-resistance electrical connection in a first position, the contact position, between the first contact element and the second contact element via the contact bridge.

To open the electrical connection, the electromagnetic actuator is electrically deactivated so that the contact bridge is moved to its open position in which the electrical connection between the first contact element and the second contact element is disconnected.

The housing cover is connected to the housing body in a gas-tight manner via an internal welded connection so that the contact chamber is completely sealed against the environment. As a result, no gas/air exchange or pressure equalization with the environment exists. There may at most be a relatively small gas/air exchange due to diffusion processes. Generally, when the arc occurs in the contact chamber, a relatively high gas pressure is suddenly generated compared to the surrounding environment which cannot be immediately equalized or reduced due to the lack of gas/air exchange and pressure equalization between the contact chamber and the surrounding environment. The high gas pressure, however, improves the extinguishing of the arcs.

The gas-tight and, for example, the internal welded connection can be produced using an ultrasonic welding process in which a so-called sonotrode of an ultrasonic welding device is placed on the outside of the housing, thereby generating friction in the material by introducing ultrasonic waves and thereby heating it. The waves should be introduced at a relatively short distance from the welding joint. The sonotrode must therefore be positioned relatively close to the joint. The distance should be less than 6 mm.

According to the present invention, the housing cover is provided with a joining groove into which a housing body wall protrudes, whereby a welding joint of the ultrasonic-welded connection is formed by the joining groove and the housing body wall. For this purpose, the housing body wall extends into the joining groove as a so-called tongue according to the tongue-and-groove principle. The housing body wall can, for example, be in direct axial contact with the joining groove. Using a sonotrode, sound waves are introduced, for example, axially, into the housing, thereby generating friction in the welding joint so that the housing body wall and the housing cover melt in the area of the joining groove and weld together. An internal weld seam is thereby formed in the joining groove since the ultrasonic waves are directed from the outside through the housing wall to the welding joint, whereby the joining groove allows the production of a precise and uniform weld seam.

The housing body wall can, for example, be provided with an energy concentration structure where the material is melted first during the welding process. The energy concentration structure, also known as energy director, is located at the axial end of the housing body wall and can, for example, be provided with a sharp-edged geometry which is configured to concentrate the energy introduced by the sonotrode via ultrasonic waves, thereby melting the joint relatively quickly and with relatively little energy input. The energy director can, for example, be provided as a roof shape, i.e., it is provided with a triangular or V-shaped cross-section and tapers toward the welding joint so that the energy director with the tapered, sharp-edged part contacts the joining groove, for example, axially. The energy director extends completely along the housing body wall and thus along the entire welding joint. The tip angle of the energy director in the contact area can, for example, be 60° to 90°, which allows the materials to be welded relatively quickly. The welding process can thereby be automated easily and cost-efficiently.

In an embodiment of the present invention, the housing cover wall can, for example, be provided with a circumferential and radially extending end wall section which has an axial end surface, wherein the joining groove is arranged in the end surface. The axial end surface faces the housing body wall axially so that it is subsequently referred to as the inner end surface. The joining groove extends axially from the end surface into the end wall section. In the circumferential direction, the joining groove extends in a ring shape and in a circumferential manner, wherein its contour corresponds to the contour of the radial housing body wall. The housing cover can thereby be seated axially on the housing body, resulting in a relatively simple and cost-efficient assembly.

In an embodiment of the present invention, the housing body wall can, for example, be provided with a radial contact chamber wall that completely encloses the contact chamber radially. The contact chamber wall can, for example, be formed integrally with the housing body wall so that the entire housing body can be manufactured in a single plastic injection molding process.

In an embodiment of the present invention, the joining groove can, for example, be provided with a groove base which can, for example, be arranged as a flat surface. The housing body wall with the, for example, sharp-edged energy director therefore does not fully contact the groove base. There is instead a linear contact that improves the melting of the materials. The joining groove can, for example, be provided with a U-shaped profile. The joining groove may alternatively also be provided with other shapes, for example, a semicircular shape or a trapezoidal shape.

In an embodiment of the present invention, the housing cover can, for example, be provided with a circumferential collar which extends in an axial direction on the radial outside of the contact chamber wall that completely encloses the contact chamber. The collar is provided with an annular shape and completely surrounds the housing cover. The collar moreover extends in the axial direction, for example, over at least 20% of the total height of the high-voltage contactor. The contact chamber wall extends in the axial direction over the entire axial height of the contact chamber and completely encloses the contact chamber in the circumferential direction. The collar extends over approximately 50% of the height of the contact chamber in the axial direction so that the protruding collar additionally reinforces the contact chamber wall and so that the housing is particularly well protected against bursting due to the high gas pressures that are generated by the arcs.

In a more advanced embodiment of the present invention, the housing cover wall, which is provided with the ultrasonic wave introduction surface, comprises a circumferential and radially extending end wall section to which the circumferential collar is connected. The end wall section can, for example, be provided with an annular shape and extends radially inwardly from the collar. The collar can, for example, be formed integrally with the end wall section so that the housing cover is relatively strong and can withstand the high stresses caused by the gas pressures in the contact chamber.

The axial end surface can, for example, be radially surrounded by the collar. The collar thereby also surrounds the joining groove so that the joining groove is not accessible from the outside. After the welded connection has been produced, the collar thus surrounds the welding joint or weld seam so that an internal welded connection is produced which is provided with a high sealing performance.

The joining groove can, for example, be arranged adjacent to a radial inner wall of the collar, whereby the collar is arranged adjacent to the contact chamber wall, so that a particularly strong housing is created. A gap is additionally formed between the housing body wall and the joining groove, on both the radial inside and the radial outside, into which the melt can flow during the welding process. This radial gap can, for example, be provided with a width of 0.05 mm to 0.5 mm. The collar additionally serves as a guide during the assembly process to guide the housing body wall into the joining groove when the housing cover is seated. An inner wall of the collar may additionally be slightly inclined for this purpose so that the opening formed by the collar widens towards the outside, which further simplifies the seating of the housing cover.

In an advantageous embodiment of the present invention, the radial contact chamber wall protrudes axially into the joining groove, wherein the welding joint is formed by the radial contact chamber wall and the joining groove. This allows the housing cover and the joining groove to be seated axially on the free end of the radial contact chamber wall during assembly, wherein the housing cover is precisely and securely aligned with the housing body by the engagement of the contact chamber wall and the joining groove.

In an advantageous embodiment of the present invention, the housing cover wall is provided with an ultrasonic wave introduction surface which is arranged on a first axial wall side of the housing cover wall, wherein the joining groove is arranged axially opposite to the ultrasonic wave introduction surface on a second wall side of the housing cover wall which is axially opposite to the first wall side. The sonotrode can be placed on the ultrasonic wave introduction surface so as to generate the ultrasonic waves and to, for example, introducer the ultrasonic waves axially into the housing cover so that the ultrasonic waves travel a relatively short distance to the welding joint formed in the joining groove. The thickness of the housing cover wall in the area of the ultrasonic wave introduction surface is just a few millimeters, for example, less than 5 mm. The distance between the welding joint and the ultrasonic wave introduction surface thereby corresponds to the thickness of the housing cover wall between them, so that the ultrasonic waves are introduced in the direct proximity of the joint, resulting in a reliable and tight weld seam.

An embodiment of the present invention is described below with reference to the enclosed drawings.

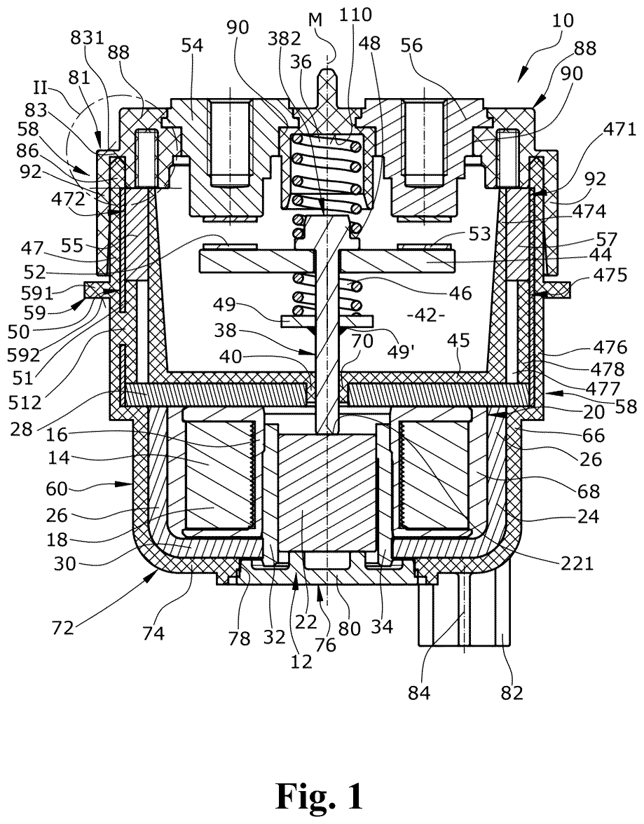

The high-voltage contactor 10 or high-voltage relay shown in FIG. 1 is used, for example, in an electrically driven motor vehicle for the electrical disconnection or connection of a traction battery from or to other electrical components. The high-voltage contactor 10 comprises an electromagnetic actuator 12 which is provided with a coil 14 that comprises a coil carrier 16 and a coil winding 18 wound thereon, a ferromagnetic iron circuit 20, and an armature 22. The ferromagnetic iron circuit 20 comprises a yoke 24 which is bent into a U-shape and whose limbs 26 rest on a back iron plate 28 or are attached to the back iron plate 28, so that the closed ferromagnetic iron circuit 20 is provided.

The yoke 24, which defines the electromagnetic flux returning path, is provided at its base section 30 with a central opening 32, whose diameter substantially corresponds to the inside diameter of the coil carrier 16. A bushing 34 is arranged in this central opening 32 in which the armature 22 is displaceable arranged and guided. When current flows through the coil 14, the armature 22 is pulled in a well-known manner against the force of a return spring 36 in the contact chamber 42 towards the back iron plate 28 into its closed position. The distal end of the return spring 36 is axially supported and radially guided in a spring support chamber 110 of the housing.

An integral actuating rod 38 contacts the armature 22 axially on its proximal flat end surface 221 on the contact chamber side and extends through a further central opening 40 in the back iron plate 28 into a contact chamber 42.

A contact bridge 44 is arranged at the end 382 of the actuating rod 38 that is opposite to the armature 22. The contact bridge 44 is pushed against a stop 48 at the end 382 of the actuating rod 38 by a spring element 46 which is designed as a helical spring, the spring element 46 being supported with its other spring end axially on a protrusion 49 of the actuating rod 38. The protrusion 49 is provided by an annular disc that is welded to the actuating rod 38 via a weld 49′. The contact bridge 44 is thereby supported by the actuating rod 38 against the spring force of the spring element 46 in a tiltable and axially movable manner. The stop 48 is also used on its distal side for the centered support of the proximal end of the return spring 36. The spring element 46 can alternatively also be designed as a leaf spring, which is supported in the center of the protrusion 49, and whose two leaf spring ends transfer the spring force to the two contact bridge ends.

A contact plate 52, 53 is attached to each end of the contact bridge 44, which is made of a material with a relatively good electrical conductivity. The first contact plate 52 is arranged axially opposite to a first contact element 54 which can in particular be connected to a high-voltage traction battery via a (not shown) busbar. The second contact plate 53 is arranged opposite to a second contact element 56 which can, for example, be connected to an electric drive motor of a motor vehicle via a busbar.

The entire high-voltage contactor 10 is arranged in a housing 58 made of plastic, the housing 58 being defined by a housing body 60 and a housing cover 88, as shown most clearly in FIG. 1. The actuator 12 is overmolded with plastic to form the housing body 60 with a housing body wall 86. This plastic surrounds the coil 14 completely radially to define a radial boundary wall 66 and also fills a space 68 radially between the coil 14 and the yoke 24. The yoke 24 itself is additionally completely radially enclosed by this plastic and is thereby shielded from the environment. The yoke 24 itself is furthermore completely surrounded radially by this plastic and is thus shielded from the environment. The back iron plate 28, which contacts the coil carrier 16 at that side which faces the coil carrier, is also covered axially by this plastic in the direction of the contact chamber 42, whereby an axial contact chamber wall 45 is provided. The further central opening 40 of the back iron plate 28 is also covered radially inwards by the plastic, exposing only a central guide opening 70 in which the actuating rod 38 is guided.

On the axial outer side 72 of the housing body 60, which is opposite the contact chamber 42, the plastic extends further radially inwards along a radially outer region 74 of the base section 30 of the yoke 24 or the actuator 12, only exposing an opening 78 in the central, radially inner section 76, which is arranged to be symmetrical to the central opening 32 but whose diameter is slightly larger to provide sufficient space for pressing in the bushing 34.

This opening 78 is closed by a plastic cover 80 which is materially bonded to the housing body 60 in the opening 78, in particular by laser welding, ultrasonic welding, or rotational vibration welding.

The housing body 60, which is manufactured by overmolding the actuator 12, furthermore defines a structure in the form of a plug housing 82, through which the connecting lines 84 to the coil winding 18 of the coil 14 are guided to the outside, so that the electrical connection of the coil 14 to a voltage source can be provided via a plug counterpart.

A circumferential radial contact chamber wall 47, which is an integral part of the housing body wall 86, additionally extends from the back iron plate 28 in extension of the plastic surrounding the actuator 12, which radially bounds the contact chamber 42 and is also integrally manufactured during the overmolding of the actuator 12 and thus defines four side walls of the contact chamber 42 in the present embodiment.

The radial contact chamber wall 47 is provided in a so-called sandwich-type construction. The radial contact chamber wall 47 is formed by a contact chamber inner wall 474 and a contact chamber outer wall 476, which are arranged parallel to and at a distance from each other. A magnetic field conducting body 50, which is formed by a ferromagnetic magnetic field conducting plate 51, is arranged between the inner contact chamber inner wall 474 and the contact chamber outer wall 476, and radially completely surrounds the contact chamber 42, wherein the radial contact chamber wall 47 or the contact chamber inner wall 474 and the contact chamber outer wall 476 are manufactured by injection molding of plastic around the magnetic field conducting plate 51 on the inside and outside. The injection molding is carried out in the same step in which the actuator 12 is injection molded, whereby the contact chamber outer wall 476 is formed integrally with the housing body 60 and the contact chamber inner wall 474 is formed integrally with the axial contact chamber wall 45. The contact chamber inner wall 474 and the contact chamber outer wall 476 are, however, connected to one another in a material-bonded manner at a plurality of locations, for example, through openings 512 in the longitudinal side walls 506 of the magnetic field conducting plate 51.

The contact chamber 42 is cuboid-shaped and therefore has a rectangular cross-section which is radially bounded by four side walls, each formed by the radial contact chamber wall 47. On the two opposite short sides, the side walls of the radial contact chamber wall 47 each have a cuboid, inward-projecting pocket 471, 472, which are open on that axial side which is opposite with respect to the actuator 12, wherein a permanent magnet 55, 57 is arranged in each pocket 471, 472. Each pocket 471, 472 and each permanent magnet 55, 57 arranged in the pocket 471, 472 is arranged radially adjacent to one of the contact plates 52, 53 of the contact bridge 44. Each permanent magnet 55, 57 is in this case aligned with respect to its magnetic poles so that the Lorentz force exerted by the magnetic fields of the permanent magnets 55, 57 deforms the arc occurring between the contact plates 52, 53 and the contact elements 54, 56 in an arc-shaped manner and, as a result of the resulting elongation and faster cooling, the arcs are thereby extinguished.

The magnetic field conducting plate 51 is, in the region of the pockets 471, 472, not completely overmolded on the inside. Each permanent magnet 55, 57 instead contacts the magnetic field conducting plate 51 on its respective short inner side, whereby the permanent magnets 55, 57 are magnetically conductively connected to one another. A stop structure 475 is arranged within each pocket 471, 472, the stop structure 475 being formed by two ribs 477 which are arranged parallel and spaced apart from each other and a wall projection 478. The wall projection 478 extends radially inwards from the inside of the magnetic field conducting plate 51. The ribs 477 each extend radially from the inner wall 474 of the contact chamber to the wall projection 478. The permanent magnets 55, 57 are in axial contact with the respective stop structure 475, whereby each permanent magnet 55, 57 is arranged in the contact chamber 42 at the height of the contact locations with respect to the axial direction.

The magnetic field conducting plate 51 additionally extends axially in the actuator direction up to the back iron plate 28 and is in axial contact with the yoke plate 28 via a flat contact surface 504. The magnetic field conducting plate 51 is thereby in a direct, magnetically conductive contact with the back iron plate 28 and thus with the ferromagnetic iron circuit 20. This results in both an increased local field strength and in an improved homogeneity of the magnetic field, whereby a relatively strong deformation of the arcs and thus a relatively fast extinguishing of the arcs is achieved.

The magnetic field conducting plate 51 is formed as a rectangular tube and is made from a flat metal strip by bending. The magnetic field conducting plate 51 is provided with four bending points 507 which form the corners of the magnetic field conducting plate 51.

The contact chamber 42 in FIG. 1 is closed axially on the axial side opposite to the axial contact chamber wall 45 by the housing cover 88, which also axially closes the pockets 471, 472. Two axial openings 90 are provided at the housing cover 88, in which the two contact elements 54, 56 are supported and fixed, for example, by injection molding.

The housing cover 88 is connected to the housing body 60 in a gas-tight manner via an ultrasonic-welded connection. The housing cover 88 comprises an ultrasonic wave insertion surface 81 on a housing cover wall 89, which is arranged on a first wall side 891 of the housing cover wall 89, wherein a welding joint 85 of the ultrasonic-welded connection is arranged on a second wall side 892 of the housing cover wall 89, which is opposite to the first wall side 891, and opposite to the ultrasonic wave insertion surface 81.

The housing cover wall 89 is formed by a circumferential and radially extending end wall section 83 which is annular and from which a circumferential collar 92 extends axially in the direction of the actuator 12. The collar 92 thereby encloses the radial contact chamber wall 47 radially and extends over about 50% of the contact chamber height. The end wall section 83 comprises an axial end surface 831 at an outer side of the housing cover 88, which faces away from the collar 92, wherein the ultrasonic wave introduction surface 81 is formed by the axial end surface 831.

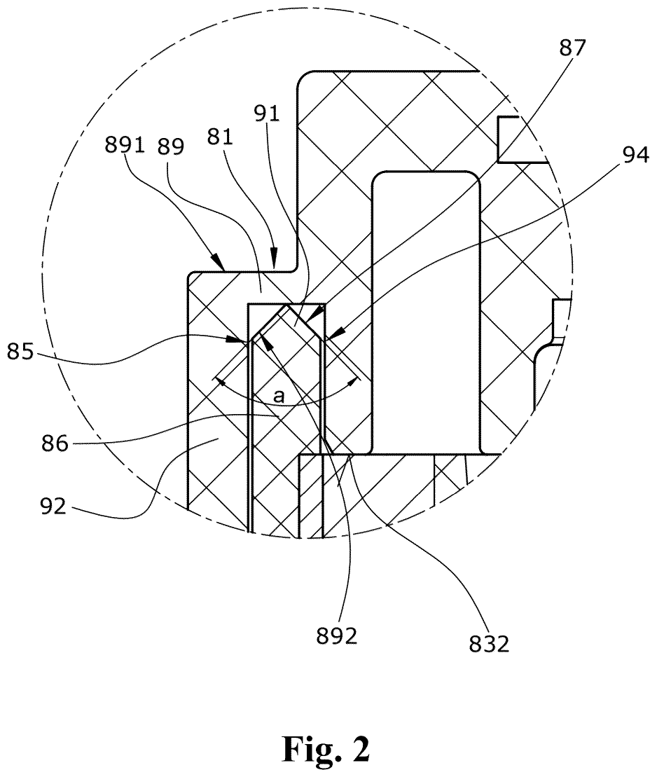

The axial end surface 831 is arranged perpendicular to the center axis M of the actuator 12 and is therefore perpendicular to the axial mounting direction of the housing cover 88. The end wall section 83 also comprises an inner axial end surface 832 which is surrounded by the collar 92, as is also shown in FIG. 2. The inner axial end surface 832 comprises an axial joining groove 94 into which the radial contact chamber wall 47, in particular the contact chamber outer wall 476, extends axially with its distal end. The radial contact chamber wall 47 comprises an energy concentration structure 87 which has a triangular or V-shaped profile. The energy concentration structure 87 thereby tapers to a sharp edge in the direction of a groove ground 91 of the joining groove 94 so that the energy concentration structure 87 contacts the groove ground 91 of the joining groove 94 axially under a line-like contact. The corner angle a of the energy concentration structure 87 is hereby approximately 90°.

The joining groove 94 extends circumferentially along the inner radial side of the collar 92 and is adjacent thereto. The joining groove 94 additionally comprises a U-shaped profile, as is shown in FIG. 2. The flat groove ground 91 and the energy concentration structure 87 define the welding joint 85 at which the housing cover 88 is welded to the housing body 60. In the axial direction, the joining groove 94 is arranged axially adjacent to the ultrasonic wave insertion surface 81 so that the ultrasonic waves of the sonotrode which is placed axially on the ultrasonic wave insertion surface 81 for producing the ultrasonic-welded connection at the axially opposite wall side of the welding joint 85 can be inserted axially and spread axially through the front wall section 83 up to the welding joint 85, so that a particularly homogeneous and tight-welded connection is produced in the joining groove 94.

The housing body 60 additionally comprises an axially acting stop 59 which is formed as a radially extending protrusion 591. An axial stop surface 592 is formed at the protrusion 591, which is arranged perpendicular to the center axis M, and via which the housing body 60 is supported axially in a corresponding supporting device during the ultrasonic welding process. The stop 59 serves as a counter support when the sonotrode is positioned axially on the ultrasonic wave insertion surface 81 to execute the welding process.

If a current flow between the traction electric motor or the charging station and the traction battery is allowed, the coil 14 is energized, causing the ferromagnetic armature 22 to be pulled towards the back iron plate 28 due to the acting electromagnetic forces. This pushes the actuating rod 38 with the contact bridge 44 and the contact plates 52, 53 against the contact elements 54, 56 so that an electric current can flow from the first contact element 54 to the second contact element 56 via the contact bridge 44 and thus from the battery to the electric motor or from the charging station to the battery. If the coil 14 is not energized, the actuating rod 38 and the armature 22 are moved by the spring force of the return spring 36 in the opposite direction to the previously acting closing force, so that the contact bridge 44 is lifted off the contact elements 54, 56 and the electric circuit is interrupted. At high currents, this results in an electric arc, which also causes an increase in pressure in the contact chamber 42.

This pressure increase can be absorbed well by the housing 58 due to the metal-reinforced contact chamber walls 45, 47 surrounding the contact chamber 42, the actuator 12 is also reliably protected, in particular by the molded axial contact chamber wall 45. A complete seal to the outside is achieved due to the sealed welding of the three housing parts so that no gas can escape from the contact chamber 42, the arc is reliably and quickly extinguished, and no gases or liquids can enter from the outside. The required installation space and assembly costs are very low.

The present invention is not limited to embodiments described herein; reference should be had to the appended claims.

### LIST OF REFERENCE CHARACTERS

10 High-voltage contactor
12 Actuator
14 Coil
16 Coil carrier
18 Coil winding
20 Ferromagnetic iron circuit
22 Armature
24 Yoke
26 Limb
28 Back iron plate
30 Base section
32 Central opening
34 Bushing
36 Return spring
38 Actuating rod
40 Further central opening
42 Contact chamber
44 Contact bridge
45 Axial contact chamber wall
46 Spring element
47 Radial contact chamber wall
48 Stop
49 Protrusion
49′ Weld
50 Field conducting body
51 Magnetic field conducting plate
52 First contact plate
53 Second contact plate
54 First contact element
55 Permanent magnet
56 Second contact element
57 Permanent magnet
58 Housing
59 Stop
60 Housing body
66 Boundary wall
68 Space
70 Central guide opening
72 Axial outer side (of housing body 60)
74 Radially outer region (of base section 30)
76 Central, radially inner section (of opening 78)
78 Opening
80 Plastic cover
81 Ultrasonic wave insertion surface
82 Plug housing
83 End wall section
84 Connecting lines
85 Welding joint
86 Housing body wall
87 Energy concentration structure
88 Housing cover
89 Housing cover wall
90 Axial opening
91 Groove ground
92 Collar
94 Joining groove
110 Spring support chamber
221 Flat end surface (of armature 22)
382 End (of actuating rod 38)
471 Pocket
472 Pocket
474 Contact chamber inner wall
475 Stop structure
476 Contact chamber outer wall
477 Rib
478 Wall projection
512 Openings
591 Protrusion
592 Stop surface
831 Axial end surface
832 Inner axial end surface
891 First side wall
892 Second side wall
a Corner angle
M Center axis

What is claimed is:

1. A high-voltage contactor comprising:
an electromagnetic actuator which comprises a coil and a ferromagnetic armature which is configured to be movable via the coil;
a housing which comprises a housing body and a housing cover, wherein,
the housing body and the housing cover are arranged to together enclose a contact chamber,
the housing cover is connected to the housing body in a gas-tight manner via an ultrasonic-welded connection,
the housing cover comprises a joining groove, and
the ultrasonic-welded connection comprises a welding joint; and
an electrically conductive contact bridge which is arranged in the contact chamber and which is configured to be displaceable by the electromagnetic actuator into a contact position in which a first stationary contact element is electrically connected to a second stationary contact element via the electrically conductive contact bridge, and into an open position in which an electrical contact between the first contact element and the second contact element is disconnected,
wherein,
a housing body wall protrudes into the joining groove, and
the welding joint of the ultrasonic-welded connection is formed by the joining groove and the housing body wall.

2. The high-voltage contactor as recited in claim 1, wherein the housing body wall comprises an energy concentration structure.

3. The high-voltage contactor as recited in claim 2, wherein the energy concentration structure comprises a V-shaped profile.

4. The high high-voltage contactor as recited in claim 1, wherein,
the joining groove comprises a groove base, and
the groove base is provided as a flat surface.

5. The high-voltage contactor as recited in claim 4, wherein the joining groove further comprises a U-shaped profile.

6. The high-voltage contactor as recited in claim 1, wherein,
the housing further comprises a housing cover wall,
the housing cover wall comprises a circumferential and radially extending end wall section which comprises an axial end surface, and
the joining groove is arranged in the axial end surface.

7. The high-voltage contactor as recited in claim 6, wherein,
the housing cover wall further comprises a first wall side, a second wall side, and an ultrasonic wave introduction surface,
the second wall side is axially opposite to the first wall side,
the ultrasonic wave introduction surface is arranged on the first wall side, and
the joining groove is arranged axially opposite to the ultrasonic wave introduction surface on the second wall side.

8. The high-voltage contactor as recited in claim 6, wherein the housing body wall comprises a radial contact chamber wall which is configured to completely enclose the contact chamber radially.

9. The high-voltage contactor as recited in claim 8, wherein,
the radial contact chamber wall is arranged to protrude axially into the joining groove, and
the welding joint is provided by the radial contact chamber wall and the joining groove.

10. The high-voltage contactor as recited claim 8, wherein,
the housing cover further comprises a circumferential collar which is arranged to extend in an axial direction at a radial outside of the radial contact chamber wall.

11. The high-voltage contactor as recited in claim 10, wherein the circumferential collar is connected to the circumferential and radially extending end wall section.

12. The high-voltage contactor as recited in claim 10, wherein the axial end surface is radially surrounded by the circumferential collar.

13. The high-voltage contactor as recited in claim 10, wherein,
the circumferential collar comprises a radial inner wall, and
the joining groove is further arranged adjacent to the radial inner wall of the circumferential collar.
